(19) United States
(12) Patent Application Publication
(10) Pub. No.: US 2013/0012012 A1
(43) Pub. Date: Jan. 10, 2013

(54) SEMICONDUCTOR PROCESS

(76) Inventors: Chien-Liang Lin, Taoyuan County (TW); Yu-Ren Wang, Tainan City (TW); Ying-Wei Yen, Miaoli County (TW); Shao-Wei Wang, Taichung City (TW); Te-Lin Sun, Kaohsiung City (TW); Szu-Hao Lai, Kaohsiung City (TW); Po-Chun Chen, Tainan City (TW); Chih-Hsun Lin, Ping-Tung County (TW); Che-Nan Tsai, Tainan City (TW); Chun-Ling Lin, Tainan City (TW); Chiu-Hsien Yeh, Tainan City (TW)

(21) Appl. No.: 13/179,558

(22) Filed: Jul. 10, 2011

(51) Int. Cl. H01L 21/28

(52) U.S. Cl. 438/591; 257/E21.19

(57) ABSTRACT

A semiconductor process includes the following steps. A substrate having an oxide layer thereon is provided. A high temperature process higher than 1000° C. is performed to form a melting layer between the substrate and the oxide layer. A removing process is performed to remove the oxide layer and the melting layer.

### BACKGROUND OF THE INVENTION

1. Field of the Invention

The present invention relates generally to a semiconductor process, and more specifically to a semiconductor process that performs a high temperature process at a temperature higher than 1000° C. to form a melting layer between a substrate and an oxide layer.

2. Description of the Prior Art

In a conventional semiconductor process, an oxide layer located on a substrate will be removed before forming semiconductor components such as a gate structure to expose the surface of the substrate, thereby enabling the semiconductor components which are formed on the substrate to have a good electrical performance. The oxide layer may be a pad oxide layer on the substrate, wherein the oxide layer will be removed after the isolation structures are formed, the Vt-well ion implantation processes are performed, etc. Furthermore, the oxide layer may be a native oxide layer formed while the substrate is exposed to the air. Regardless of the way the oxide layer is formed, it should be removed before the semiconductor components are formed.

In current processes, however, the surface of the substrate is unsmooth or has a certain amount of defects after the oxide layer is removed. This leads to undesirable structures of the semiconductor components formed on the substrate, thereby degrading the electrical performance.

Therefore, a semiconductor process, which can form a smooth substrate surface while decreasing the amount of defects in the substrate surface after the oxide layer is removed, is desired.

### SUMMARY OF THE INVENTION

The present invention provides a semiconductor process to solve the problems of an unsmooth substrate surface which has defects.

The present invention provides a semiconductor process including the following steps. A substrate having an oxide layer thereon is provided. A high temperature process higher than 1000° C. is performed to form a melting layer between the substrate and the oxide layer. A removing process is performed to remove the oxide layer and the melting layer.

Above all, the present invention provides a semiconductor process, which performs a high temperature process higher than 1000° C. to form a melting layer between the substrate and the oxide layer, and then performs a removing process to remove the oxide layer and the melting layer. In doing this, the exposed substrate after the oxide layer and the melting layer are removed has a smoother surface with fewer defects, and thereby the semiconductor components formed on the substrate have an enhanced electrical performance.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 schematically depicts a cross-sectional view of a semiconductor process according to one embodiment of the present invention.

FIG. 2 schematically depicts a cross-sectional view of a semiconductor process according to one embodiment of the present invention.

FIG. 3 schematically depicts a cross-sectional view of a semiconductor process according to one embodiment of the present invention.

FIG. 4 schematically depicts a cross-sectional view of a semiconductor process according to one embodiment of the present invention.

FIG. 5 schematically depicts a cross-sectional view of a transistor process according to one embodiment of the present invention.

FIG. 6 schematically depicts a cross-sectional view of a transistor process according to one embodiment of the present invention.

FIG. 7 schematically depicts a cross-sectional view of a transistor process according to one embodiment of the present invention.

FIG. 8 schematically depicts a cross-sectional view of a transistor process according to one embodiment of the present invention.

FIG. 9 schematically depicts a cross-sectional view of a transistor process according to one embodiment of the present invention.

FIG. 10 schematically depicts a cross-sectional view of a transistor process according to one embodiment of the present invention.

### DETAILED DESCRIPTION

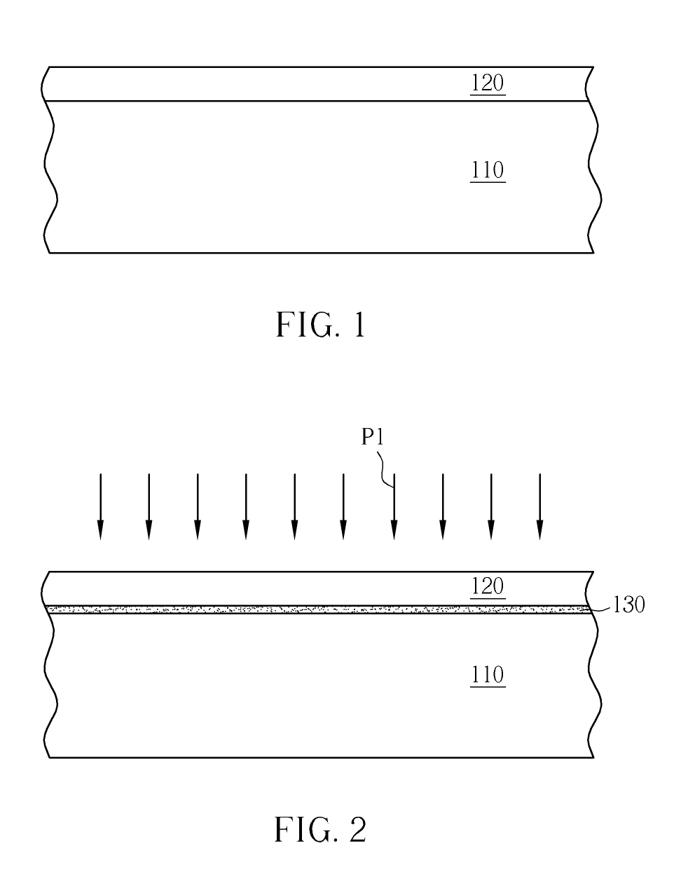

FIGS. 1-4 schematically depict a cross-sectional view of a semiconductor process according to one embodiment of the present invention. A substrate 110 is provided and an oxide layer 120 is located on the substrate 110. The substrate 110 may be a semiconductor substrate such as a silicon substrate, a silicon-containing substrate, or a silicon-on-insulator substrate, etc. The oxide layer 120 may be a pad oxide layer, or a native oxide layer, etc. The materials of the oxide layer 120 may be a silicon dioxide layer, but are not limited thereto. By using a pad oxide layer as an example, a pad oxide layer and a nitride layer are sequentially formed on a silicon substrate. The nitride layer and the pad oxide layer are sequentially patterned and the substrate 110 is etched to form a trench by using a photoresist layer as a mask. An isolation structure fills in the trench utilizing a method such as chemical vapor deposition (CVD), or high aspect ratio process (HARP). Then, the excess material of the isolation structure is removed by applying chemical-mechanical polishing (CMP) and using the nitride layer as a polish stop layer, thereby forming a flat surface of the isolation structure by trimming until the top surface of the nitride layer is reached. The nitride layer is then removed by using hot phosphoric acid, for example. The pad oxide layer still remains and needs to be removed; however, the methods of removing the pad oxide layer considerably affect the qualities of the surface of the substrate 110 contacting the pad oxide layer. If the pad oxide layer is not removed entirely, the surface of the substrate 110 will not be smooth, or amounts of defects will be generated in the surface of the substrate 110, and the electrical performance of semiconductor structures sequentially formed on the substrate 110, such as a gate structure, will be degraded. Also, when the surface of the substrate 110 is exposed to the air, the surface of the substrate 110 will be oxidized so that a native oxide layer is formed on the substrate 110. The native oxide layer should be removed before semiconductor processes for forming semiconductor components on the substrate 110, such as a gate dielectric layer etc, are performed. The methods of removing the native oxide layer are important to avoid the said unsmooth surface of the substrate 110, the damaged crystalline structure or defects from being formed.

As shown in FIG. 2, as the oxide layer 120 is on the substrate 110, a high temperature process P1 higher than 1000° C. is performed in the present invention to form a melting layer 130 between the substrate 110 and the oxide layer 120. The high temperature process P1 may be a rapid thermal processing (RTP) process, a laser-spike annealing (LSA) process, etc. In a preferred embodiment, the processing temperature of the rapid thermal processing (RTP) process is 1000° C.˜1100° C., preferably with nitrogen gas imported and performing at one atmosphere. In anther preferred embodiment, the processing temperature of the laser-spike annealing (LSA) process is 1200° C.˜1300° C. and preferably performing at one atmosphere. In this embodiment, the high temperature process P1 is a laser-spike annealing (LSA) process because the laser-spike annealing (LSA) process has a higher processing temperature than the rapid thermal processing (RTP) process, thereby the interface of the substrate 110 and the oxide layer 120 can be melted efficiently and rapidly so that the melting layer 130 is formed. This also means that impurities and dislocations on the surface of the substrate 110 can get into the oxide layer 120 due to the high temperature. Please note there may be other high temperature processes applied in the present invention to form the melting layer 130 between the substrate 110 and the oxide layer 120.

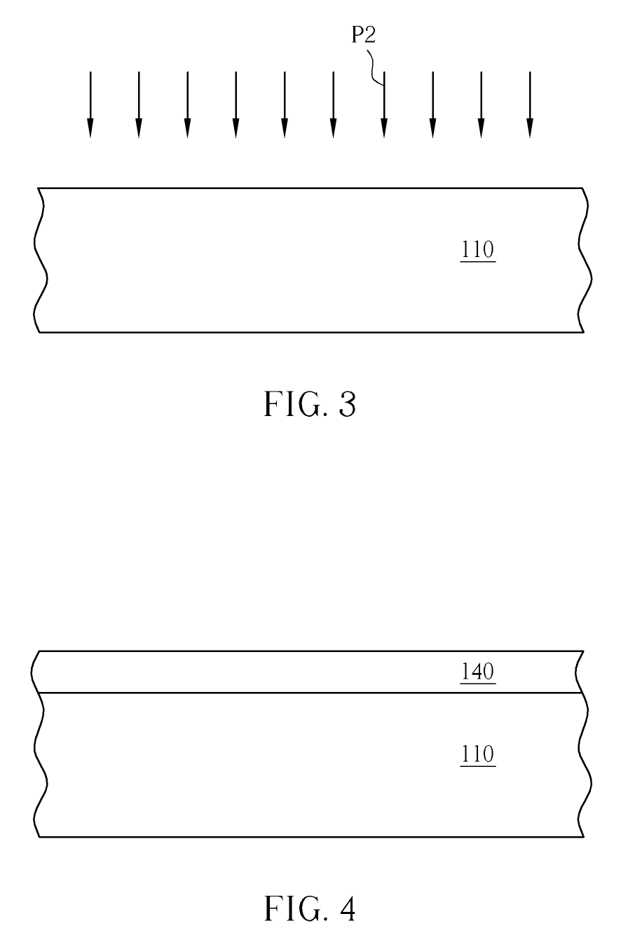

As shown in FIG. 3, a removing process P2 is performed to remove the oxide layer 120 and the melting layer 130. In one case, the removing process P2 may be a hydrofluoric acid removing process and the processing time may be 300 seconds. In another case, the removing process P2 may be another process depending upon requirements. Furthermore, the removing process P2 may further include a Standard clean 1 (SC1) process, a Standard clean 2 (SC2) process, etc. for helping remove the oxide layer 120 and the melting layer 130, and further removing the residues that remain after the prior removing process P2. In doing this, the present invention applying the high temperature process P1 paired with and performed prior to the removing process P2 can make the surface of the substrate 110 more smooth than the prior art after the oxide layer 120 is removed.

As shown in FIG. 4, a gate dielectric layer 140 is formed on the substrate 110. The gate dielectric layer 140 may be formed by an in-situ steam generation (ISSG) process or a thermal oxidation process. In one case, the gate dielectric layer 140 may be a silicon dioxide layer, but it is not limited thereto.

Due to the material and the structure of the gate dielectric layer 140 affecting the Effective Oxide Thickness (EOT) and the Gate Oxide Leakage (Jg) of the sequentially formed gate structure, the present invention provides two preferred embodiments representing improved methods of forming the gate dielectric layer 140, to further enhance the performance of the semiconductor structure.

In the first embodiment, a fluoride containing thermal oxidation process is performed (replacing the in-situ steam generation (ISSG) process) to form a fluoride containing oxide layer, such as a fluorine doped silicon oxide (SiOF) layer. In one case, the fluoride containing thermal oxidation process may be a fluorine molecule containing thermal oxidation process, a tetrafluoride containing thermal oxidation process, etc. In this way, not only can the material of the gate dielectric layer 140 be changed to increase the electrical performance, but also the reliability of the gate structure and the carrier mobility of the gate channel can be enhanced by fluoride diffusing into the substrate 110.

In the second embodiment, a deuterium (D2) or a nitrous oxide (N2O) in-situ steam generation process is performed (replacing the in-situ steam generation (ISSG) process or the thermal oxidation process) to form an oxide layer, such as a silicon dioxide layer. In this way, the forming oxide layer can have a denser structure than the oxide layer formed by the prior art, and thereby the dielectric constant of the oxide layer increases and the Effective Oxide Thickness (EOT) of the oxide layer decreases. The second embodiment has deuterium or nitrous oxide imported to replace hydrogen imported in the prior art. Therefore, the easily broken and unstable bonds such as Si—H bonds generated during the prior art processes can be replaced by the non-easily broken and stable bonds such as Si-D bonds, and the structure of the forming oxide layer can be more dense.

Otherwise, a silicon nitride layer, which may be formed by an Atomic Layer Deposition (ALD) process, may be selectively formed before the gate dielectric layer 140 is formed, to be used as a barrier layer for increasing the dielectric constant of the gate structure. A dielectric layer having a high dielectric constant may be formed on the gate structure 140 after the gate dielectric layer 140 is formed, wherein the dielectric layer having a high dielectric constant may include a metal containing oxide layer, such as a rare earth metal oxide layer, and may be a group selected from hafnium oxide (HfO₂), hafnium silicon oxide (HfSiO), hafnium silicon oxynitride (HfSiON), aluminum oxide (AlO), lanthanum oxide (La₂O₃), lanthanum aluminum oxide (LaAlO), tantalum oxide (Ta₂O₃), zirconium oxide (ZrO₂), zirconium silicon oxide (ZrSiO), hafnium zirconium oxide (HfZrO), strontium bismuth tantalite (SrBi₂Ta₂O₉, SBT), lead zirconate titanate (PbZrₓTi₁₋ₓO₃, PZT) and barium strontium titanate (BaxSr₁₋ₓTiO₃, BST). The dielectric layer having a high dielectric constant can be integrated into relative processes, but it is not limited thereto. Otherwise, a gate layer may be directly formed on the gate dielectric layer 140. The gate layer may be a poly-silicon layer, a sacrificed gate layer, a metal gate layer etc., depending upon the need.

An embodiment, which describes a transistor process applying the semiconductor process of the present invention, is presented in the following to clarify the present invention. The semiconductor process of the present invention can also be applied to various other semiconductor processes.

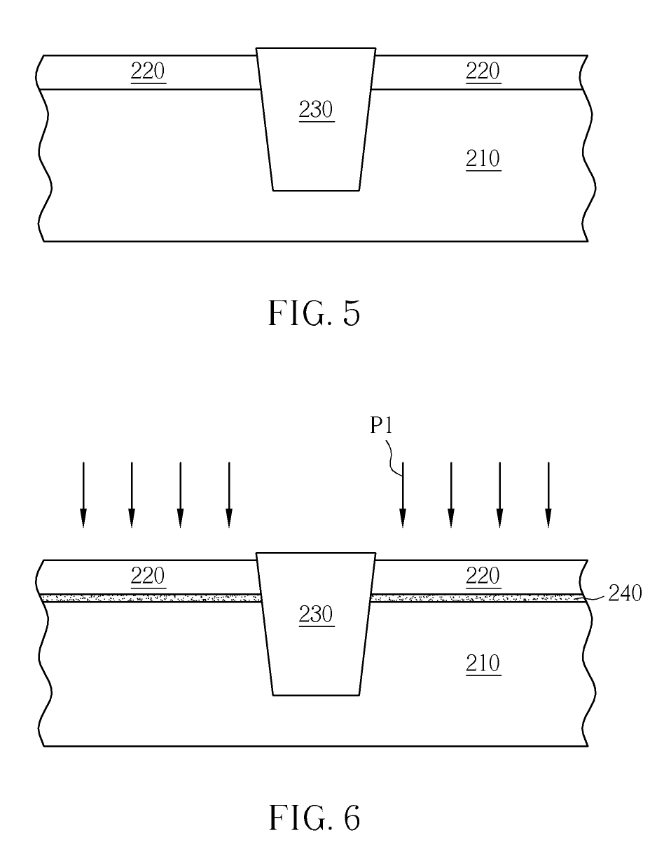

FIGS. 5-10 schematically depict a cross-sectional view of a transistor process according to one embodiment of the present invention. As shown in FIG. 5, a substrate 210, and an oxide layer 220 and an isolation structure 230 formed thereon are provided, wherein the oxide layer 220 may be a pad oxide layer or a native oxide layer, and the isolation structure 230 may be a shallow trench isolation structure. As shown in FIG. 6, a high temperature process P1 higher than 1000° C. is performed to form a melting layer 240 between the substrate 210 and the oxide layer 220. The high temperature process P1 may be a rapid thermal processing (RTP), or a laser-spike annealing (LSA) process, etc. In a preferred embodiment, the processing temperature of the rapid thermal processing (RTP) is 1000° C.˜1100° C., preferably with nitrogen gas imported and performing at one atmosphere. In anther preferred embodiment, the processing temperature of the laser-spike annealing (LSA) process is 1200° C.˜1300° C., and preferably performed at one atmosphere. In this embodiment, the high temperature process P1 is a laser-spike annealing (LSA) process because the laser-spike annealing (LSA) process has a higher processing temperature than the rapid thermal processing (RTP) process, meaning the interface of the substrate 210 and the oxide layer 220 can be melted efficiently and rapidly, so that the melting layer 240 is formed.

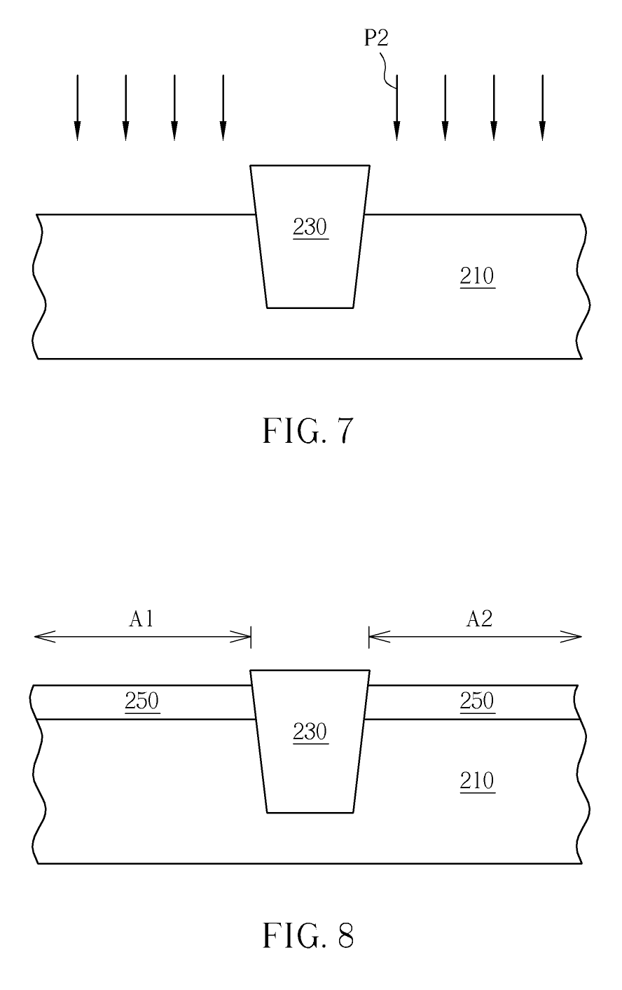

As shown in FIG. 7, a removing process P2 is performed to remove the oxide layer 220 and the melting layer 240. In one case, the removing process P2 may be a hydrofluoric acid removing process and the processing time may be 300 seconds. In another case, the removing process P2 may be another process, depending upon the need.

As shown in FIG. 8, a gate dielectric layer 250 is located on the substrate 210 and is respectively located in the first active region A1 and the second active region A2 beside the isolation structure 230. The gate dielectric layer 250 may be formed by an in-situ steam generation (ISSG) process or a thermal oxidation process. Alternatively, the gate dielectric layer 250 may be formed by the improved methods of forming the gate dielectric layer 140 of the present invention, which have been detailed in the above. For example, a fluoride containing thermal oxidation process is performed to form a fluoride containing oxide layer, such as a fluorine doped silicon oxide (SiOF) layer. In one case, the fluoride containing thermal oxidation process may be a fluorine molecule containing thermal oxidation process, or a tetrafluoride containing thermal oxidation process, etc. In this way, not only can the material of the gate dielectric layer 250 be changed to increase the electrical performance, but also the reliability of the gate structure and the carrier mobility of the gate channel can be enhanced by fluorine diffusing into the substrate 210. Or, a deuterium (D2) or a nitrous oxide (N2O) in-situ steam generation process can be performed to form an oxide layer, such as a silicon dioxide layer. In this way, the formed oxide layer can have a denser structure than the oxide layer formed by the method of the prior art, meaning the dielectric constant of the oxide layer increases and the Effective Oxide Thickness (EOT) of the oxide layer decreases. The present invention has deuterium or nitrous oxide imported to replace hydrogen imported in the prior art. Therefore, the easily broken and unstable bonds such as Si—H bonds generated during the prior art processes can be replaced by the non-easily broken and stable bonds such as Si-D bonds, and the structures of the forming oxide layer can be more dense.

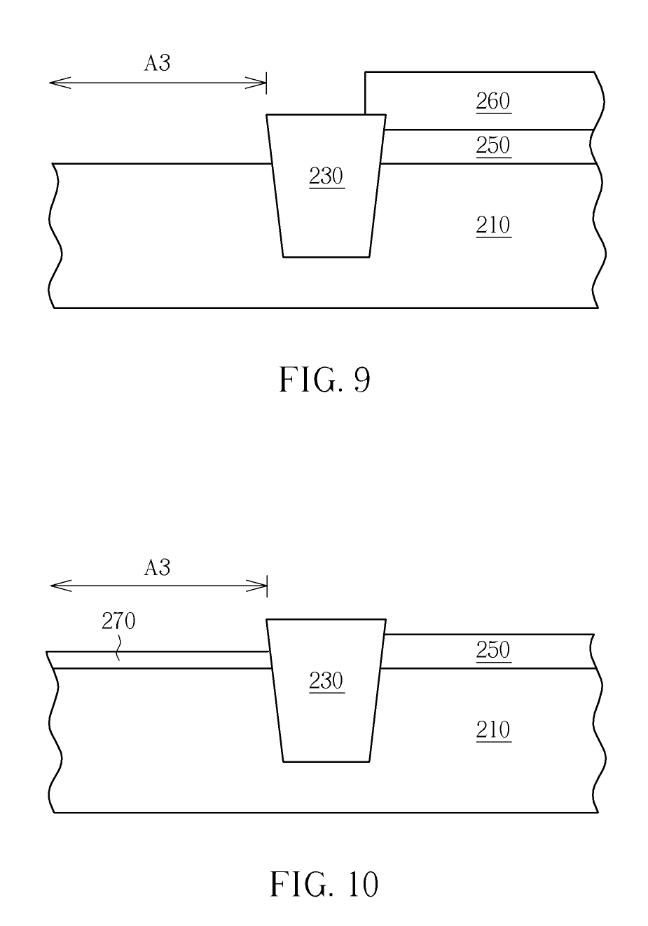

As shown in FIG. 9, a photoresist layer is formed and patterned by processes such as photolithography to form a patterned photoresist layer 260 and define a removed region A3. The removed region A3 overlaps with the first active region A1 in this embodiment, but the removed region A3 may also overlap with the second active region A2, the first active region A1 and the second active region A2, or other not-shown regions, depending upon the need. An etching process is performed to remove the gate dielectric layer 250 in the removed region A3. The etching process may be a dry etching process or a wet etching process. In one case, the etching process may be a wet etching process, such as a wet etching process with the etchant containing hydrofluoric acid, a Standard clean 1 (SC1) process or a Standard clean 2 (SC2) process, etc.

As shown in FIG. 10, a gate dielectric layer 270 with a thickness thinner than the gate dielectric layer 250 is formed on the substrate 210 in the removed region A3. This means there are two different thicknesses of gate dielectric layers (the gate dielectric layer 250 and the gate dielectric layer 270) respectively formed on the first active region A1 and the second active region A2. Dielectric layers having a high dielectric constant or gate layers can be further formed on the gate dielectric layer 250 or the gate dielectric layer 270 after the gate dielectric layer 270 is formed, to finish the sequential transistor processes. The dielectric layer having a high dielectric constant may be a metal containing dielectric layer, including a hafnium oxide layer, a zirconium oxide layer, etc. The gate layer may be a poly-silicon layer, a sacrificed gate layer, a metal gate layer, etc.

Then, a gate layer, a spacer, a source/drain region, etc. may be formed after the dielectric layer having a high dielectric constant is formed. The respective forming methods may be a gate-first process or a gate-last process, wherein the gate-last process may be a gate last for high-k first process or a gate last for high-k last process. Otherwise, the present invention may be also applied to a gate last for buffer layer (corresponding to the gate dielectric layer of the present invention) first processor a gate last for buffer layer last process. The steps of the transistor processes are not described herein.

The present invention provides a semiconductor process which performs a high temperature process higher than 1000° C. to form a melting layer between the substrate and the oxide layer, and then performs a removing process to remove the oxide layer and the melting layer. In doing this, the exposed substrate after the oxide layer and the melting layer are removed has a smoother surface with fewer defects, thereby enhancing the electrical performance of semiconductor devices formed on the substrate.

The present invention also provides methods of forming a gate dielectric layer including: (1) performing a fluoride containing thermal oxidation process to form a fluoride containing oxide layer; or, (2) performing a deuterium (D2) or a nitrous oxide (N2O) in-situ steam generation (ISSG) process to form an oxide layer. Thus, due to fluoride diffusing into the substrate in method (1), the carrier mobility of the gate channel is enhanced; due to deuterium (D₂) or nitrous oxide (N₂O) forming more stable bonds with the substrate (such as silicon substrate) in method (2), the structure of the gate dielectric layer can be more dense, and the dielectric constant of the gate dielectric layer increases while the Effective Oxide Thickness of the gate dielectric layer decreases.

Those skilled in the art will readily observe that numerous modifications and alterations of the device and method may be made while retaining the teachings of the invention.

1. A semiconductor process, comprising:
providing a substrate having an oxide layer located thereon;
performing a high temperature process higher than 1000° C. to form a melting layer between the substrate and the oxide layer; and
after the high temperature process, performing a removing process to remove the oxide layer and the melting layer.

2. The semiconductor process according to claim 1, wherein the oxide layer comprises a pad oxide layer or a native oxide layer.

3. The semiconductor process according to claim 1, wherein the high temperature process comprises a rapid thermal processing (RTP) process or a laser-spike annealing (LSA) process.

4. The semiconductor process according to claim 3, wherein the processing temperature of the rapid thermal processing (RTP) process is 1000° C.˜1100° C.

5. The semiconductor process according to claim 4, wherein the rapid thermal processing (RTP) process has nitrogen gas imported and is performed at one atmosphere.

6. The semiconductor process according to claim 3, wherein a processing temperature of the laser-spike annealing (LSA) process is 1200° C.˜1300° C.

7. The semiconductor process according to claim 6, wherein the laser-spike annealing (LSA) process is performed at one atmosphere.

8. The semiconductor process according to claim 1, wherein the removing process comprises a hydrofluoric acid containing removing process.

9. The semiconductor process according to claim 8, wherein the processing time of the hydrofluoric acid containing removing process is 300 seconds.

10. The semiconductor process according to claim 1, further comprising:
after performing the removing process, forming a gate dielectric layer on the substrate.

11. The semiconductor process according to claim 10, wherein the gate dielectric layer is formed by an in-situ steam generation (ISSG) process or by a thermal oxidation process.

12. The semiconductor process according to claim 10, wherein the gate dielectric layer comprises a silicon dioxide layer.

13. The semiconductor process according to claim 10, wherein the step of forming the gate dielectric layer comprises:
performing a fluoride containing thermal oxidation process to form a fluoride containing oxide layer.

14. The semiconductor process according to claim 13, wherein the fluoride containing thermal oxidation process comprises a fluorine molecule containing thermal oxidation process, or a tetrafluoride containing thermal oxidation process.

15. The semiconductor process according to claim 10, wherein the step of forming the gate dielectric layer comprises:
performing a deuterium (D2) containing or a nitrous oxide (N2O) containing in-situ steam generation (ISSG) process to form an oxide layer.

16. The semiconductor process according to claim 1, further comprising:
after performing the removing process, forming a dielectric layer having a high dielectric constant.

17. The semiconductor process according to claim 1, further comprising:
after performing the removing process, forming a gate layer.

18. The semiconductor process according to claim 10, further comprising:
before forming the gate dielectric layer, forming a silicon nitride layer.
